(19) United States
(12) Patent Application Publication
(10) Pub. No.: US 2020/0033387 A1
(43) Pub. Date: Jan. 30, 2020

(54) Multiple Load Center Electric Meter Panel

(71) Applicants: Jarrod Tucker, Riverside, CA (US); James Rowe, Orange, CA (US)

(72) Inventors: Jarrod Tucker, Riverside, CA (US); James Rowe, Orange, CA (US)

(21) Appl. No.: 16/046,970

(22) Filed: Jul. 26, 2018

(51) Int. Cl. G01R 21/00; H01R 25/00

(52) U.S. Cl. CPC G01R 21/00; H01R 25/006

(57) ABSTRACT

The device allows for multiple meter and load centers to be installed in a single device in order to obtain metering rates through utilities. The device allows for multiple meters and load centers to be used or a single meter and load center depending on need to be utilized for electric utility metering services.

### FIELD OF INVENTION

The technology relates to the general field of metering electric power usage, and has certain specific application to multiple utility rate, multiple meter service.

### BACKGROUND

The invention relates generally to electric meter panels. More specifically, the invention relates to single device with multiple load centers, multiple rate capability, electric vehicle ready, and combination electric meter panels. Current options available require the installation of a second separate meter panel in order to obtain a second meter for multiple rate electric billing options. In order to obtain a second meter for a separate billing rate the homeowner currently has two options. (1) Overheard required the installation of a second panel with a separate weather head (mast protruding through the roof) and separate point of attachment. (2) The installation of a second meter panel that is fed from an underground service required the installation of a second panel and an intercept type pull box in order to split a single service into multiple feeds. These current options require a greater deal of construction which may not be feasible. These options require large amounts of wall room which may not be available. Due to the extra equipment required, pull box and second panel, the framing of the wall may not be able to accommodate the required space. The underground intercept pull box is not an easy option of space and may not be framing compatible. These options also make it difficult to gain utility approval because of overall spacing requirements, standard utility service requirements, or functional space needs. These large space requirements, intrusive construction requirements, and visually un-pleasing aesthetics make it difficult for homeowners to optimize utility offered rates for cost savings.

### SUMMARY

The invention is a multiple socket, multiple rate compatible and multiple load center combination meter panel within a single device. This allows for minimal construction above the required amounts for a common meter panel change or upgrades. The panel uses electric bussing in a single panel in order to provide multiple meter sockets, 2 or more, required to in order to utilize utility or otherwise cost saving plans and or rates provided but were previously unattainable. It also provides separate load centers that allow the homeowner to have separate main disconnects for each meter socket. The multiple use panel provides the option for an electric vehicle ready panel for future electric vehicle charger installation or current installation in order to utilize special utility rate options for cost savings. The invention eliminates the need for a second point of service, a second and separate meter panel, and/or intercept pull box to split an existing service feed into multiple feeds, which is extremely costly and requires large amounts of construction to an existing building. In some cases, this may not even be possible to meet all electrical codes and utility requirements making multiple panels and/or junction boxes not a viable option. This invention combines all required needs for metering and distribution (load center's) for a second panel in a single device. Allowing combination panels for multiple utility rates, multiple sockets, multiple load centers and available in a single electric panel.

### BRIEF DESCRIPTION OF THE DRAWINGS

Various embodiments of the invention are disclosed in the following detailed description and accompanying drawings.

FIG. 1 Illustrates a front view a multiple load center, multiple meter electrical meter panel in a two load center configuration.

FIG. 2 Illustrates an electrical busing configuration of a multiple load center electric meter panel.

FIG. 3 Illustrates an electrical single line of one configuration to allow multiple meters and load centers.

FIG. 4 Illustrates an alternative embodiment with more than two load centers and meter socket combination.

### DETAILED DESCRIPTION AND PREFERRED EMBODIMENT

The following is a detailed description of exemplary embodiments to illustrate the principles of the invention. The embodiments are provided to illustrate aspects of the invention, but the invention is not limited to any embodiment. The scope of the invention encompasses numerous alternatives, modifications and equivalent; it is limited only by the claims.

Numerous specific details are set forth in the following description in order to provide a thorough understanding of the invention. However, the invention may be practiced according to the claims without some or all of these specific details. For the purpose of clarity, technical material that is known in the technical fields related to the invention has not been described in detail so that the invention is not unnecessarily obscured.

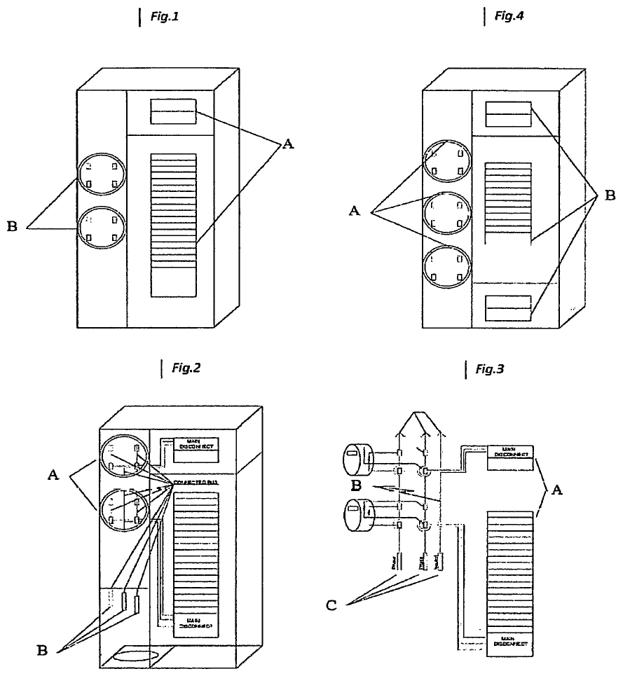

### FIG. 1—A Mechanical Device.

FIG. 1 illustrates an overview of a preferred embodiment. It is a single device with multiple load centers (A) and multiple meter sockets (B).

### FIG. 2—A Mechanical Component

FIG. 2 illustrates an electrical busing diagram which connects (B) to multiple meter sockets that will feed separate load centers (A).

### FIG. 3—A Mechanical Component

FIG. 3 depicts and electric single line showing one way the internal components are connected electrically. The single point of service connection (C) connects to the bussing feeding the separate load centers (A) and the separate metering compartments (B).

### Alternate Embodiment

FIG. 4 depicts an alternate embodiment with a configuration of more than two load centers and meter sockets. This alternative embodiment is not limited to how many load centers can be achieved.

What is claimed is:

1. A device to measure electric power usage with multiple meters:
a device having multiple and separate meter sockets,
a device having multiple and separate main disconnects,
a device having multiple and separate load centers.

2. A device as in claim 1 wherein a compartment with multiple main disconnects coupled to above mentioned meter sockets.

3. A device as in claim 1 wherein a section for multiple load centers coupled to the main disconnects;

4. A device as in claim 1 wherein a configuration of solid bussing coupling the separate load centers to the separate main disconnects and to the separate meter sockets;

5. A device as in claim 1 wherein a configuration of non-solid bussing coupling the separate load centers to the main disconnects and to the meter sockets
